(19) United States
(12) Patent Application Publication
(10) Pub. No.: US 2025/0277849 A1
(43) Pub. Date: Sep. 4, 2025

(54) METHOD AND DEVICE FOR AN INTEGRATED CIRCUIT

(71) Applicant: Robert Bosch GmbH, Stuttgart (DE)

(72) Inventor: Robert Kornhaas, Spraitbach (DE)

(21) Appl. No.: 19/061,083

(22) Filed: Feb. 24, 2025

(30) Foreign Application Priority Data
Mar. 1, 2024 (DE) 10 2024 201 918.6

(51) Int. Cl. G01R 31/28

(52) U.S. Cl. CPC G01R 31/2896

(57) ABSTRACT

A method for a first integrated circuit that is arranged on a substrate together with at least one further, second, integrated circuit. The method includes: sending a test signal to the at least one further integrated circuit; and receiving a feedback signal associated with the test signal from the at least one further integrated circuit.

### FIELD

The present invention relates to at least one method for an integrated circuit.

The present invention further relates to at least one device for an integrated circuit.

### SUMMARY

Some examples of the present invention relate to a method, for example a computer-implemented method, for a first integrated circuit that is arranged on a substrate together with at least one further, for example second, integrated circuit, said method comprising: sending a test signal to the at least one further integrated circuit; receiving a feedback signal associated with the test signal from the at least one further integrated circuit. In some examples, this allows monitoring of the transmission quality of the test signal.

In some examples of the present invention, the method comprises: influencing an operation of at least one component of the first integrated circuit on the basis of the feedback signal.

In some examples of the present invention, the first integrated circuit and the at least one further integrated circuit are each designed as a chip, for example a chiplet, wherein, for example, the first integrated circuit and the at least one further integrated circuit form a multi-chiplet system.

In some examples of the present invention, a first communication channel is used for sending the test signal, wherein, for example, the first communication channel is a main band of a communication interface that connects at least the first integrated circuit and the second integrated circuit to one another, wherein, for example, the communication interface is a chiplet interface, e.g. a standardized chiplet interface, e.g. of the type Universal Chiplet Interconnect Express, UCIe, for example UCIe 1.0.

In some examples of the present invention, a second communication channel is used for receiving the feedback signal, wherein, for example, the second communication channel is a side band of a or the communication interface that connects at least the first integrated circuit and the second integrated circuit to one another, wherein, for example, the communication interface is a chiplet interface, e.g. a standardized chiplet interface, e.g. of the UCIe type, for example UCIe 1.0.

In some examples of the present invention, influencing the operation comprises: controlling, for example influencing, a signal level with which the first integrated circuit sends information, for example data, for example via a or the first communication channel, to the at least one further integrated circuit.

In some examples of the present invention, the method comprises: providing the test signal, wherein, for example, the test signal has at least one signal pattern, for example a predefinable signal pattern, for example a test pattern, and, optionally, using the test signal.

In some examples of the present invention, the providing comprises providing an encrypted test signal or test pattern. For example, a standardized method for encryption can be used.

In some examples of the present invention, the method comprises: controlling, for example influencing, a or the signal level with which the first integrated circuit sends information, for example data, for example via a or the first communication channel, to the at least one further integrated circuit, for example on the basis of the feedback signal, wherein, for example, the controlling, for example influencing, is carried out dynamically, for example during operation of at least the first integrated circuit, for example repeatedly, for example periodically, for example multiple times within an error tolerance time.

Some examples of the present invention relate to a method, for example a computer-implemented method, for a or the second integrated circuit that is arranged on a or the substrate together with at least one or the first integrated circuit, said method comprising: receiving a or the test signal from the first integrated circuit; evaluating the received test signal; creating, on the basis of the evaluation, a or the feedback signal associated with the test signal; sending the feedback signal to the first integrated circuit.

In some examples of the present invention, as described above, the first integrated circuit and the second integrated circuit are each designed as a chip, for example a chiplet, wherein, for example, the first integrated circuit and the at least one further integrated circuit form a multi-chiplet system.

In some examples of the present invention, a first communication channel is used for receiving the test signal, wherein, for example, the first communication channel is a main band of a communication interface that connects at least the first integrated circuit and the second integrated circuit to one another, wherein, for example, the communication interface is a chiplet interface, e.g. a standardized chiplet interface, e.g. of the type Universal Chiplet Interconnect Express, UCIe, for example UCIe 1.0.

In some examples of the present invention, a second communication channel is used for sending the feedback signal, wherein, for example, the second communication channel is a side band of a or the communication interface that connects at least the first integrated circuit and the second integrated circuit to one another, wherein, for example, the communication interface is a chiplet interface, e.g. a standardized chiplet interface, e.g. of the UCIe type, for example UCIe 1.0.

In some examples of the present invention, the evaluation comprises at least one of the following elements: a) checking the received test signal, e.g. for correctness or agreement, e.g. with a signal pattern, for example a predefinable signal pattern, for example a test pattern, or b) analyzing a signal level of the received test signal, or c) analyzing a signal quality of the received test signal, or d) using at least one method based on artificial intelligence, for example machine learning, or e) using a multi-stage assessment system.

Some examples of the present invention relate to a device for carrying out the method according to the disclosure.

Some examples of the present invention relate to an integrated circuit, for example for a multi-chiplet system comprising multiple chiplets, comprising at least one device according to the disclosure, wherein, for example, the device or a functionality of the device is integrated into the integrated circuit.

Some examples of the present invention relate to a system, for example a multi-chiplet system, comprising at least one device according to the disclosure or at least one integrated circuit according to the disclosure.

Some examples of the present invention relate to a product, for example a control unit, for example for a motor vehicle, comprising at least one device according to the disclosure.

Some examples of the present invention relate to a vehicle, for example a motor vehicle, comprising at least one device according to the disclosure and/or at least one product, for example a control unit, according to the disclosure.

Some examples of the present invention relate to a computer-readable storage medium comprising commands that, when executed by a computer, cause said computer to carry out the method according to the disclosure.

Some examples of the present invention relate to a computer program comprising commands that, when the computer program is executed by a computer, cause said computer to carry out the method according to the disclosure.

Some examples of the present invention relate to a data carrier signal that characterizes and/or transmits the computer program according to the disclosure.

Some examples of the present invention relate to a use of the method according to the disclosure and/or of the device according to the disclosure and/or of the integrated circuit according to the disclosure and/or of the system according to the disclosure and/or of the product according to the disclosure and/or of the vehicle according to the disclosure and/or of the computer-readable storage medium according to the disclosure and/or of the computer program according to the disclosure and/or of the data carrier signal according to the disclosure for at least one of the following elements: a) ensuring data communication between the first integrated circuit and the at least one further, for example second, integrated circuit, or b) increasing a robustness of data communication with respect to the first integrated circuit, for example between the first integrated circuit and the at least one further, for example second, integrated circuit, or c) increasing a reliability of data communication with respect to the first integrated circuit, or d) increasing an availability of the first integrated circuit and/or of a system comprising the first integrated circuit, or e) increasing a design quality and/or manufacturing quality, for example on the basis of the feedback of findings from an operation of the first integrated circuit.

Further features, possible applications and advantages of the present invention can be found in the following description of examples of the present invention, which are shown in the figures. In this case, all of the features described or shown form the subject matter of the present invention individually or in any combination, irrespective of their wording or representation in the description or in the figures.

### BRIEF DESCRIPTION OF THE DRAWINGS

FIG. 1 schematically shows a simplified flow diagram, according to an example embodiment of the present invention.

FIG. 2 schematically shows a simplified block diagram, according to an example embodiment of the present invention.

FIG. 3 schematically shows a simplified flow diagram, according to an example embodiment of the present invention.

FIG. 4 schematically shows a simplified flow diagram, according to an example embodiment of the present invention.

FIG. 5 schematically shows a simplified flow diagram, according to an example embodiment of the present invention.

FIG. 6 schematically shows a simplified block diagram, according to an example embodiment of the present invention.

FIG. 7 schematically shows a simplified diagram, according to an example embodiment of the present invention.

FIG. 8 schematically shows a simplified block diagram, according to an example embodiment of the present invention.

FIG. 9 schematically shows examples of uses, according the present invention.

### DETAILED DESCRIPTION OF EXAMPLE EMBODIMENTS

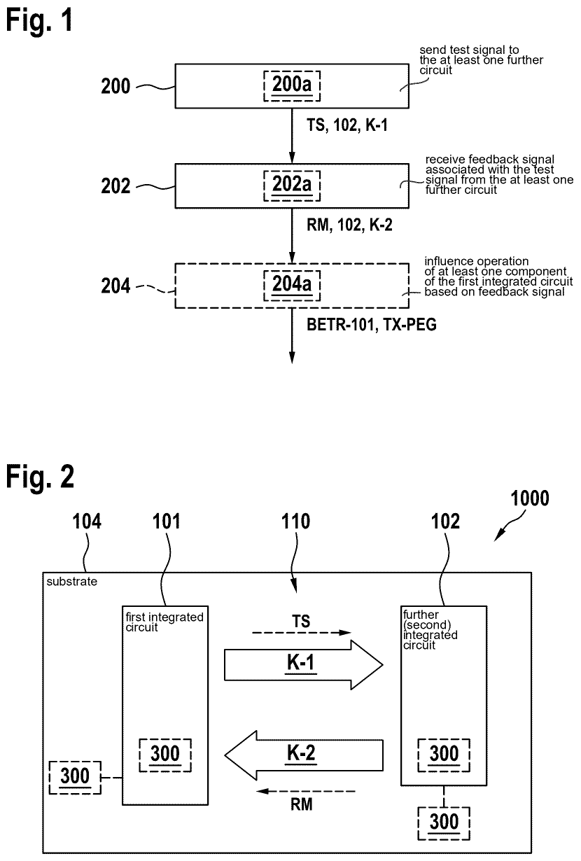

Some examples, FIG. 1, 2, relate to a method, for example a computer-implemented method, for a first integrated circuit 101 that is arranged on a substrate 104 together with at least one further, for example second, integrated circuit 102, said method comprising: sending 200 a test signal TS to the at least one further integrated circuit 102; receiving 202 a feedback signal RM associated with the test signal TS (for example dependent on the test signal TS or formed on the basis of the test signal TS) from the at least one further integrated circuit 102. In some examples, this allows monitoring of the transmission quality of the test signal TS.

In some examples, FIG. 1, the method comprises: influencing 204 an operation BETR-101 of at least one component of the first integrated circuit 101 on the basis of the feedback signal RM. In some examples, FIG. 2, the first integrated circuit 101 and the at least one further integrated circuit 102 are each designed as a chip, for example a chiplet, wherein, for example, the first integrated circuit 101 and the at least one further integrated circuit 102 form a multi-chiplet system 1000.

In some examples, FIG. 1, a first communication channel K-1 is used for sending 200 the test signal TS, see block 200a, wherein, for example, the first communication channel K-1 is a main band of a communication interface 110 (FIG. 2) that connects at least the first integrated circuit 101 and the second integrated circuit 102 to one another, wherein, for example, the communication interface 110 is a chiplet interface, e.g. a standardized chiplet interface, e.g. of the type Universal Chiplet Interconnect Express, UCIe, for example UCIe 1.0.

In some examples, FIG. 1, a second communication channel K-2 is used for receiving 202 the feedback signal RM, see block 202a, wherein, for example, the second communication channel K-2 is a side band of a or the communication interface 110 that connects at least the first integrated circuit 101 and the second integrated circuit 102 to one another.

In some examples, FIG. 1, influencing 204 the operation BETR-101 comprises: controlling, for example influencing, 204a a signal level TX-PEG with which the first integrated circuit 101 sends information, for example data, for example via a or the first communication channel K-1, to the at least one further integrated circuit 102. In some examples, a control, for example in the sense of a closed-loop control, of the signal level TX-PEG is possible, on the basis of the feedback signal RM.

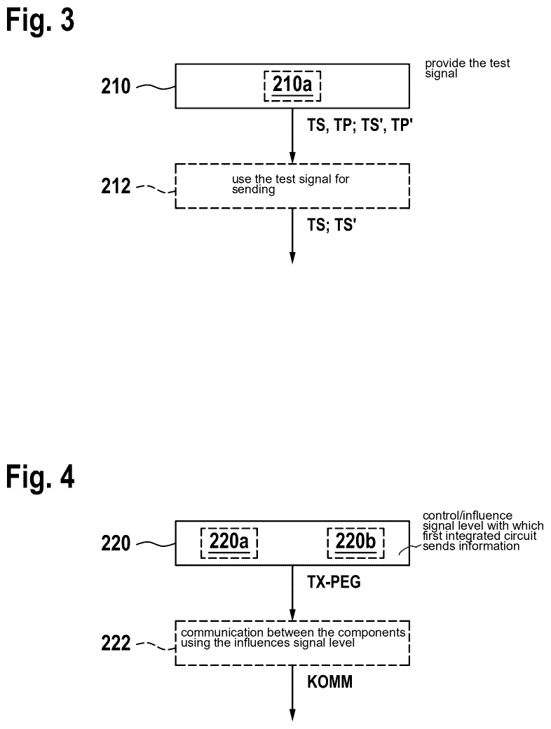

In some examples, FIG. 3, the method comprises: providing 210 the test signal TS, wherein, for example, the test signal TS has at least one signal pattern, for example a predefinable signal pattern, for example a test pattern, TP, and, optionally, using 212 the test signal TS, for example for sending 200 (FIG. 1).

In some examples, FIG. 3, the providing 210 comprises providing 210a an encrypted test signal TS' or test pattern TP′.

In some examples, FIG. 4, the method comprises: controlling 220, for example influencing 220a, a or the signal level TX-PEG with which the first integrated circuit 101 sends information, for example data, for example via a or the first communication channel K-1 (FIG. 2), to the at least one further integrated circuit 102, for example on the basis of the feedback signal RM, wherein, for example, the controlling 220, for example influencing 220a, is carried out dynamically, for example during operation of at least the first integrated circuit 101, see block 220b, for example repeatedly, for example periodically, for example multiple times within an error tolerance time. The optional block 222 symbolizes an optional communication KOMM between the components 101, 102, for example using the signal level TX-PEG influenced according to block 220.

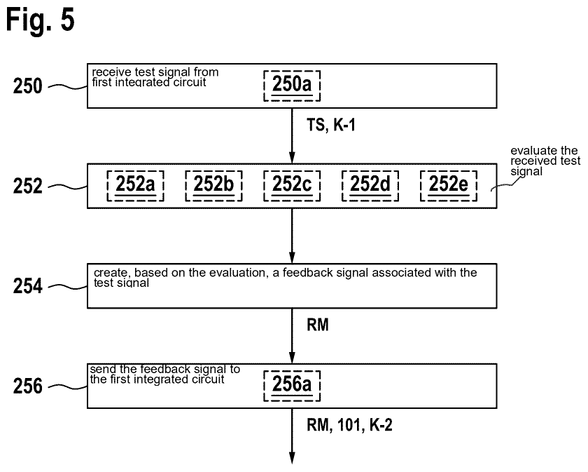

Some examples, FIG. 5, relate to a method, for example a computer-implemented method, for a or the second integrated circuit 102 (FIG. 2) that is arranged on a or the substrate 104 together with at least one or the first integrated circuit 101, said method comprising: receiving 250 a or the test signal TS from the first integrated circuit 101; evaluating 252 the received test signal TS; creating 254, on the basis of the evaluation 252, a or the feedback signal RM associated with the test signal TS; sending 256 the feedback signal RM to the first integrated circuit 101.

In some examples, as described above, the first integrated circuit 101 and the second integrated circuit 102 are each designed as a chip, for example a chiplet, wherein, for example, the first integrated circuit 101 and the at least one further integrated circuit 102 form a multi-chiplet system 1000.

In some examples, FIG. 5, a first communication channel K-1 is used for receiving 250 the test signal TS, see block 250a, wherein, for example, the first communication channel is a main band of a communication interface 110 that connects at least the first integrated circuit 101 and the second integrated circuit 102 to one another, wherein, for example, the communication interface 110 is a chiplet interface, e.g. a standardized chiplet interface, e.g. of the UCIe type, for example UCIe 1.0.

In some examples, FIG. 5, a second communication channel K-2 is used for sending 256 the feedback signal RM, see block 256a, wherein, for example, the second communication channel K-2 is a side band of a or the communication interface 110 that connects at least the first integrated circuit and the second integrated circuit to one another, wherein, for example, the communication interface is a chiplet interface, e.g. a standardized chiplet interface, e.g. of the UCIe type, for example UCIe 1.0.

In some examples, FIG. 5, the evaluation 252 comprises at least one of the following elements: a) checking 252a the received test signal TS, e.g. for correctness or agreement, e.g. with a signal pattern, for example a predefinable signal pattern, for example a test pattern, TP, or b) analyzing 252b a signal level of the received test signal TS, or c) analyzing 252c a signal quality of the received test signal TS, or d) using 252d at least one method based on artificial intelligence (AI), for example machine learning (ML), for example for the testing 252a and/or for the analysis 252b and/or 252c, or e) using 252e a multi-stage assessment system, for example for an assessment of results of the evaluation 252, for example instead of a binary assessment (e.g. pass/fail).

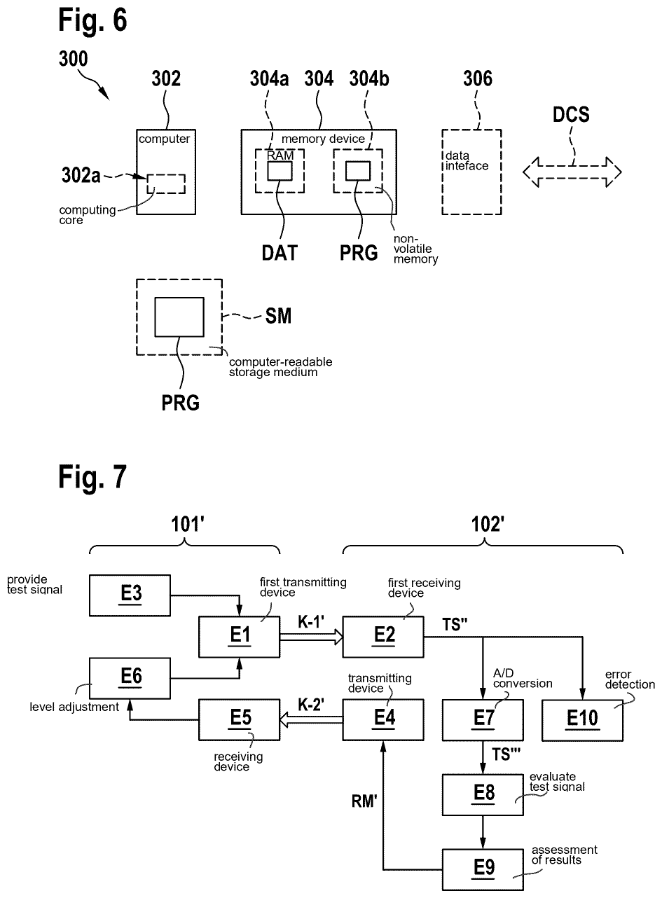

Some examples, FIG. 6, relate to a device 300 for carrying out the method according to the disclosure.

In some examples, FIG. 6, the device 300 comprises: a computing device (“computer”) 302 having at least one computing core 302a, a memory device 304 assigned to the computing device 302 for at least temporarily storing at least one of the following elements: a) data DAT (e.g. data associated with the test signal TS and/or data associated with the feedback signal RM and/or data associated with the evaluation 252); b) computer program PRG, for example for carrying out the method according to the disclosure.

In further examples, the memory device 304 has a volatile memory (e.g. a random access memory (RAM)) 304a, and/or a non-volatile (NVM) memory (e.g. a flash EEPROM) 304b, or a combination thereof or with other types of memory not explicitly mentioned.

In further examples, the device 300 is designed as a hardware circuit, for example a pure hardware circuit (not shown).

Further examples, FIG. 6, relate to a computer-readable storage medium SM comprising commands PRG that, when executed by a computer 302, cause said computer to carry out the method according to the disclosure.

Further examples relate to a computer program PRG comprising commands that, when the program PRG is executed by a computer 302, cause said computer to carry out the method according to the disclosure.

Further examples relate to a data carrier signal DCS that characterizes and/or transmits the computer program PRG according to the disclosure. The data carrier signal DCS can be received, for example, via an optional data interface 306 of the device 300.

Some examples, FIG. 2, relate to an integrated circuit, e.g. a chiplet, 101, 102, for example for a multi-chiplet system 1000 comprising multiple chiplets, comprising at least one device 300 according to the disclosure, wherein, for example, the device 300 or a functionality of the device 300 is integrated into the integrated circuit 101, 102 (or, in some examples, e.g. arranged on the common substrate 104).

Some examples, FIG. 2, relate to a system, for example a multi-chiplet system, 1000, comprising at least one device 300 according to the disclosure or at least one integrated circuit 101, 102 according to the disclosure.

FIG. 7 schematically shows a simplified diagram according to some examples. Element E1 symbolizes a first transmitting device of a first chiplet 101′, for example designed to transmit data via a UCIe main band channel K-1′ to a first receiving device E2 of a second chiplet 102′. Element E3 symbolizes the provision of a test signal, for example an encrypted test signal TS′, which in some examples can be transmitted to the first receiving device E2 by means of the first transmitting device E1 via the UCIe main band channel K-1, and element TS″ symbolizes the test signal received by the second chiplet 102′.

In some examples, the second chiplet 102′ forms a feedback signal RM′ on the basis of the received encrypted test signal TS″, which can be sent by means of a transmitting device E4 of the second chiplet 102 via a UCIe side band channel K-2′ to a corresponding receiving device E5 of the first chiplet 101′.

In some examples, the first chiplet 101′ performs a level adjustment E6 of a level for information to be transmitted to the second chiplet 102′ via the UCIe main band channel K-1′, for example on the basis of the feedback signal RM′ obtained from the second chiplet 102′.

Element E7 symbolizes an analog/digital conversion according to some examples, for example of at least a part of the received test signal TS″, for example by means of an analog/digital converter based on the delta-sigma principle.

Element E8 symbolizes an evaluation of the test signal TS′″ digitized by means of element E7 according to some examples, for example using methods based on AI, for example ML.

Element E9 symbolizes an assessment of results of the evaluation E8 according to some examples, for example using a multi-stage assessment system, which leads, for example, to the feedback signal RM′. For example, the feedback signal RM′ can indicate whether or in what manner or to what extent the first chiplet 101′ should adjust its transmission level, see block E6.

In further examples, findings gained by means of the element E8 can be used, for example, for manufacturing further chiplets or systems containing chiplets and/or for testing them, for example in the context of manufacturing.

Element E10 symbolizes an error detection according to some examples, for example for the detection of at least one of the following elements: a) electrical errors, e.g. DC errors (e.g. open, short plus/GND, crosstalk), or b) timing errors (e.g. relating to edge steepness, latency times, . . . ), or c) plausibility errors (e.g. freeze data, value range, . . . ).

Further aspects and examples are described below, which, in further examples, can each be combined individually or in any combination with one another with at least one of the aspects and/or examples described above.

In some examples, FIG. 7, communication, e.g. of user data between the chiplets 101′, 102′, takes place unidirectionally, e.g. via a particular main band channel, of which the channel K-1′ from the chiplet 101′ to the chiplet 102′ is shown by way of example in FIG. 7 (but not a possibly existing further main band channel from the chiplet 102′ to the chiplet 101′).

In some examples, FIG. 7, statuses and/or other information, e.g. relevant to operations, can be transmitted via the elements E4, E5 via the side band channel K-2′, e.g. in addition to the feedback signal RM′.

The principle according to the disclosure allows, in some examples, the provision of multi-chiplet systems 1000 in which, for example, different chiplets 101, 102, . . . can each be assigned to different, for example application-specific, domains such as in the automotive sector, body, chassis, ADAS, IVI. In further examples, different types of chiplets and/or chiplets with different architectures (e.g. GPU, CPU, HWA, . . . ) can be combined to form a multi-chiplet system, wherein communication between the chiplets can be ensured according to the principle according to the disclosure.

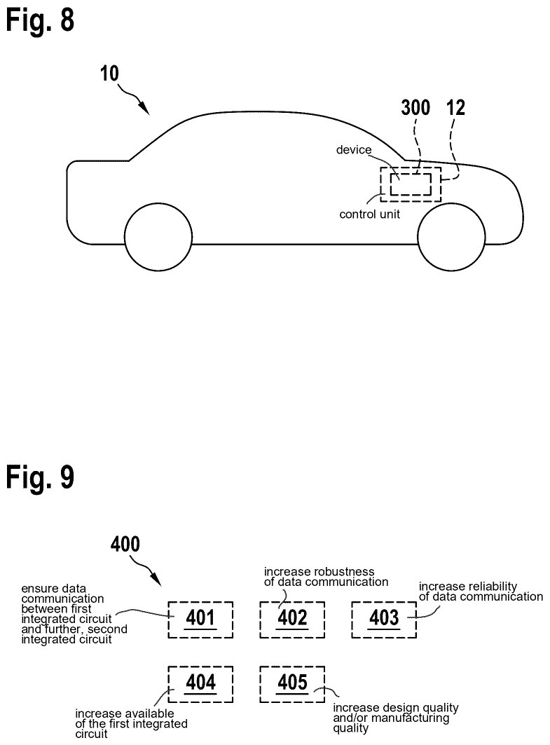

Some examples, FIG. 8, relate to a product, for example a control unit, 12, for example for a motor vehicle 10, comprising at least one device 300 according to the disclosure.

Some examples, FIG. 8, relate to a vehicle, for example a motor vehicle, 10, having at least one device 300 according to the disclosure and/or at least one product, for example a control unit, 12 according to the disclosure.

Some examples, FIG. 9, relate to a use 400 of the method according to the disclosure and/or of the device 300 according to the disclosure and/or of the integrated circuit 101, 102 according to the disclosure and/or of the system 1000 according to the disclosure and/or of the product 12 according to the disclosure and/or of the vehicle 10 according to the disclosure and/or of the computer-readable storage medium SM according to the disclosure and/or of the computer program PRG according to the disclosure and/or of the data carrier signal DCS according to the disclosure for at least one of the following elements: a) ensuring 401 data communication between the first integrated circuit 101 and the at least one further, for example second, integrated circuit 102, or b) increasing 402 a robustness of data communication with respect to the first integrated circuit, for example between the first integrated circuit and the at least one further, for example second, integrated circuit, or c) increasing 403 a reliability of data communication with respect to the first integrated circuit, or d) increasing 404 an availability of the first integrated circuit and/or of a system 1000 comprising the first integrated circuit, or e) increasing 405 a design quality and/or manufacturing quality, for example on the basis of the feedback of findings from operation of the first integrated circuit.

1-23. (canceled)

24. A method for a first integrated circuit that is arranged on a substrate together with at least one further integrated circuit, the method comprising the following steps:
sending a test signal to the at least one further integrated circuit; and
receiving a feedback signal associated with the test signal from the at least one further integrated circuit.

25. The method according to claim 24, further comprising:
influencing an operation of at least one component of the first integrated circuit based on the feedback signal.

26. The method according to claim 24, wherein the first integrated circuit and the at least one further integrated circuit are each a chiplet, and wherein the first integrated circuit and the at least one further integrated circuit form a multi-chiplet system.

27. The method according to claim 24, wherein a first communication channel is used for sending the test signal, wherein the first communication channel is a main band of a communication interface that connects at least the first integrated circuit and the at least one further integrated circuit to one another, wherein the communication interface is a chiplet interface of a type Universal Chiplet Interconnect Express (UCIe).

28. The method according to claim 24, wherein a second communication channel is used for receiving the feedback signal, wherein the second communication channel is a side band of a communication interface that connects at least the first integrated circuit and the at least one further integrated circuit to one another, wherein the communication interface is a chiplet interface of a type Universal Chiplet Interconnect Express (UCIe).

29. The method according to claim 25, wherein the influencing of the operation includes: controlling a signal level with which the first integrated circuit sends information via a first communication channel to the at least one further integrated circuit.

30. The method according to claim 24, further comprising:
providing the test signal, wherein the test signal has at least one signal pattern, and
using the test signal.

31. The method according to claim 30, wherein the providing includes providing the test signal as an encrypted test signal or encrypted test pattern.

32. The method according to claim 24, further comprising:
controlling a signal level with which the first integrated circuit sends information via a first communication channel, to the at least one further integrated circuit, based on the feedback signal, wherein the controlling is carried out dynamically during operation of at least the first integrated circuit, repeatedly.

33. A method for a second integrated circuit that is arranged on a substrate together with at least one first integrated circuit, said method comprising the following steps:
receiving a test signal from the first integrated circuit;
evaluating the received test signal;
creating, based on the evaluation, a feedback signal associated with the test signal; and
sending the feedback signal to the first integrated circuit.

34. The method according to claim 33, wherein the first integrated circuit and the second integrated circuit are a chiplet, and wherein the first integrated circuit and the second integrated circuit form a multi-chiplet system.

35. The method according to claim 33, wherein a first communication channel is used for receiving the test signal, wherein the first communication channel is a main band of a communication interface that connects at least the first integrated circuit and the second integrated circuit to one another, and wherein the communication interface is a chiplet interface of a type of Universal Chiplet Interconnect Express (UCIe).

36. The method according to claim 24, wherein a second communication channel is used for sending the feedback signal, wherein the second communication channel is a side band of a communication interface that connects at least the first integrated circuit and the second integrated circuit to one another, and wherein the communication interface is a chiplet interface of a a type of Universal Chiplet Interconnect Express (UCIe).

36. The method according to claim 24, wherein the evaluation includes at least one of the following elements: a) checking the received test signal for correctness or agreement with a signal pattern, or b) analyzing a signal level of the received test signal, or c) analyzing a signal quality of the received test signal, or d) using at least one method based on artificial intelligence including machine learning, or e) using a multi-stage assessment system.

37. A device configured to carry out a method for a first integrated circuit that is arranged on a substrate together with at least one further integrated circuit, the method comprising the following steps:
sending a test signal to the at least one further integrated circuit; and
receiving a feedback signal associated with the test signal from the at least one further integrated circuit.

38. An integrated circuit for a multi-chiplet system including multiple chiplets, the integrated circuit comprising:
at least one device configured to carry out a method for a first integrated circuit that is arranged on a substrate together with at least one further integrated circuit, the method including the following steps:
sending a test signal to the at least one further integrated circuit; and
receiving a feedback signal associated with the test signal from the at least one further integrated circuit,
wherein the device is integrated into the integrated circuit.

39. The integrated circuit according to claim 38, wherein the integrated circuit is included in the multi-chiplet system.

40. The device according to claim 37, wherein the device is includes in a control unit for a motor vehicle.

41. The device according to claim 40, wherein the control unit is included in the motor vehicle.

42. A non-transitory computer-readable storage medium on which are stored commands for a first integrated circuit that is arranged on a substrate together with at least one further integrated circuit, the commands, when executed by a computer, causing the computer to perform the the following steps:
sending a test signal to the at least one further integrated circuit; and
receiving a feedback signal associated with the test signal from the at least one further integrated circuit.

43. The method according to claim 24, wherein in method is used for at least one of the following elements: a) ensuring data communication between the first integrated circuit and the at least one further integrated circuit, or b) increasing a robustness of data communication with respect to the first integrated circuit, between the first integrated circuit and the at least one further integrated circuit, or c) increasing a reliability of data communication with respect to the first integrated circuit, or d) increasing an availability of the first integrated circuit and/or of a system including the first integrated circuit, or e) increasing a design quality and/or manufacturing quality, based on feedback of findings from operation of the first integrated circuit.
